(19) United States
(12) Patent Application Publication
(10) Pub. No.: US 2025/0132221 A1
(43) Pub. Date: Apr. 24, 2025

(54) ELECTRONIC PACKAGE

(71) Applicant: SILICONWARE PRECISION INDUSTRIES CO., LTD., Taichung City (TW)

(72) Inventors: Dai-Fei LI, Taichung City (TW); Liang-Yi HUNG, Taichung City (TW); Chia-Cheng CHEN, Taichung City (TW); Yu-Po WANG, Taichung City (TW)

(73) Assignee: SILICONWARE PRECISION INDUSTRIES CO., LTD., Taichung City (TW)

(21) Appl. No.: 18/754,902

(22) Filed: Jun. 26, 2024

(30) Foreign Application Priority Data
Oct. 19, 2023 (TW) 112140032

(51) Int. Cl. H01L 23/367; H01L 23/00; H01L 23/373; H01L 23/498

(52) U.S. Cl. CPC H01L 23/3675; H01L 23/3736; H01L 23/49866; H01L 24/16; H01L 24/32; H01L 24/73; H01L 2224/16225; H01L 2224/32225; H01L 2224/73204; H01L 2924/16152

(57) ABSTRACT

An electronic package is provided and includes: a carrier structure, an electronic component disposed on the carrier structure, a heat dissipation structure disposed on the electronic component, a heat conductor sandwiched between the electronic component and the heat dissipation structure, a first intermetallic compound layer formed between the heat dissipation structure and the heat conductor, and a second intermetallic compound layer formed between the heat conductor and the electronic component. Therefore, stable connections can be formed between the heat dissipation structure, the heat conductor and the electronic component via the first intermetallic compound layer and the second intermetallic compound layer to improve heat dissipation effect.

### BACKGROUND

### 1. Technical Field

The present disclosure relates to an electronic package, and more particularly, to an electronic package with a heat dissipation structure.

### 2. Description of Related Art

With the rise and vigorous development of various applications and technologies that require high-speed computing, such as electronic sports (esports) games, high-resolution audio and video multimedia, and autonomous driving, as well as requirements for miniaturization of related equipment, the number of components contained in a semiconductor chip with package structures such as flip chip ball grid array (FCBGA) is not only increasing day by day, but the processing and computing speed are also getting faster and faster, causing the heat generated therefrom more considerable, and the requirements for heat dissipation structures are getting higher as well.

FIG. 1 is a schematic cross-sectional view of a conventional semiconductor package 1. As shown in FIG. 1, the semiconductor package 1 includes a packaging substrate 10, a semiconductor chip 11 mounted on the upper side of the packaging substrate 10 in a flip-chip manner, and a heat sink 12. The heat sink 12 is disposed on the upper surface of the semiconductor chip 11 via a thermal interface material (TIM) 13. Since the main component of the heat sink 12 is copper, a nickel (Ni) layer 121 is usually plated on the surface of the heat sink 12 in order to prevent oxidation from occurring on the surface of the heat sink 12. Further, in order to effectively bond the heat sink 12 to the thermal interface material 13, a nickel/gold layer 122 is usually plated on the local portion of the heat sink 12 that is to be bonded to the thermal interface material 13.

However, the aforementioned additional nickel layer 121 and nickel/gold layer 122 will increase the process cost. In addition, the thermal interface material 13 often cannot be effectively bonded with the semiconductor chip 11 in practice, resulting in poor product reliability. Therefore, how to overcome the aforementioned problems in the prior art has become an urgent issue to be addressed.

### SUMMARY

In view of the various shortcomings of the prior art, the present disclosure provides an electronic package, which comprises: a carrier structure; an electronic component disposed on the carrier structure; a heat conductor disposed on the electronic component; a heat dissipation structure disposed on the electronic component, wherein the heat conductor is sandwiched between the electronic component and the heat dissipation structure; a first intermetallic compound layer formed between the heat dissipation structure and the heat conductor; and a second intermetallic compound layer formed between the heat conductor and the electronic component.

In the aforementioned electronic package, the first intermetallic compound layer has a material and a thickness different from a material and a thickness of the second intermetallic compound layer, and the thickness of the first intermetallic compound layer is greater than the thickness of the second intermetallic compound layer. For instance, the first intermetallic compound layer is made of Cu₂In, and the second intermetallic compound layer is made of Ni₃In₇.

In the aforementioned electronic package, the heat conductor is a thermal interface material layer. For instance, the thermal interface material layer is made of metal indium (In).

In the aforementioned electronic package, the present disclosure further comprises a metal anti-oxidation layer formed on an outer surface of the heat dissipation structure. For instance, the metal anti-oxidation layer is made of metal nickel (Ni).

In the aforementioned electronic package, the heat dissipation structure is made of metal copper (Cu).

In the aforementioned electronic package, before the first intermetallic compound layer is formed, a non-metal anti-oxidation layer is formed on an inner surface of the heat dissipation structure. For instance, the non-metal anti-oxidation layer is made of an imidazole compound.

In the aforementioned electronic package, before the second intermetallic compound layer is formed, an interface metal layer is formed between the heat conductor and the electronic component. For instance, the interface metal layer is a nickel/gold (Ni/Au) layer.

Through the implementation of the present disclosure, the first intermetallic compound layer is formed between the heat dissipation structure and the heat conductor, and the second intermetallic compound layer is formed between the heat conductor and the electronic component, so that stable connections can be formed between the heat dissipation structure, the heat conductor and the electronic component to improve heat dissipation effect. The present disclosure can choose to only form a metal anti-oxidation layer (nickel layer) on the outer surface of the heat dissipation structure to save process cost.

### BRIEF DESCRIPTION OF THE DRAWINGS

FIG. 1 is a schematic cross-sectional view showing a conventional semiconductor package.

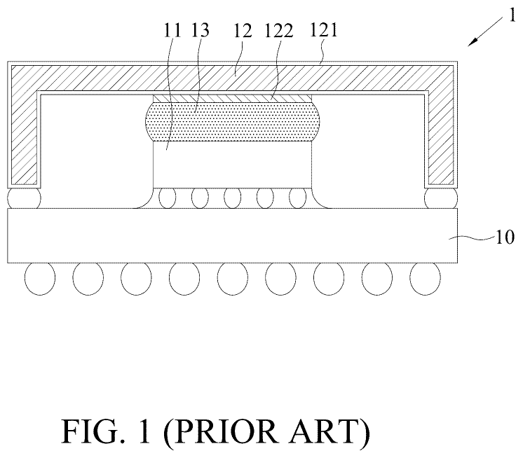

FIG. 2A to FIG. 2B are schematic cross-sectional views showing a manufacturing method of an electronic package of the present disclosure.

FIG. 3 is a schematic cross-sectional view showing another embodiment of FIG. 2A

### DETAILED DESCRIPTION

Implementations of the present disclosure are illustrated using the following specific embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” and the like recited herein are for illustrative purposes only, and are not meant to limit the scope in which the present disclosure can be implemented. Any variations or modifications to their relative relationships, without changes in the substantial technical content, should also to be regarded as within the scope in which the present disclosure can be implemented.

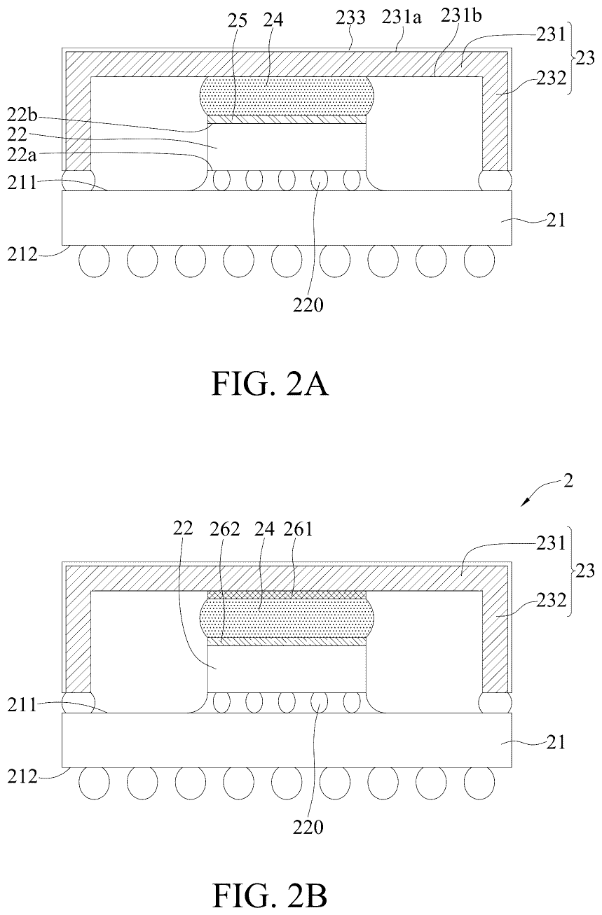

FIG. 2A and FIG. 2B are schematic cross-sectional views showing a manufacturing method of an electronic package 2 of the present disclosure. As shown in FIG. 2A, at least one electronic component 22 is firstly disposed on a carrier structure 21, and a heat dissipation structure 23 is disposed on the electronic component 22 via a heat conductor 24.

The carrier structure 21 is, for example, a packaging substrate with a circuit layer, a through-silicon interposer (TSI) with conductive through-silicon vias (TSVs), or a board of other types. The carrier structure 21 has a first surface 211 and a second surface 212 opposing the first surface 211, and the circuit layer is, for example, a fan-out redistribution layer (RDL).

It can be understood that the carrier structure 21 can also be a base material, a component, or a structure of a carrying component, such as a lead frame, a wafer, or the carrier structure 21 can be a plate body with metal routings, but the present disclosure is not limited to as such.

The electronic component 22 can be an active element, a passive element, a packaging module, or a combination thereof, wherein the active element is, for example, a semiconductor chip, and the passive element is, for example, a resistor, a capacitor, an inductor, etc.

In an embodiment, the electronic component 22 is a semiconductor chip and has an active surface 22a and an inactive surface 22b opposing the active surface 22a, and the active surface 22a is electrically connected to the carrier structure 21 in a flip-chip manner via a plurality of conductive bumps 220; alternatively, the electronic component 22 can also be electrically connected to the carrier structure 21 in a wire-bonding manner via a plurality of bonding wires (not shown); or the electronic component 22 can be directly in contact with the carrier structure 21. However, methods for electrically connecting the electronic component 22 to the carrier structure 21 are not limited to the above.

The heat dissipation structure 23 is, for example, a heat dissipation sheet, a heat dissipation lid, or other components or structures with equivalent functions. In an embodiment, a heat dissipation lid is adopted for example, the heat dissipation structure 23 has a top sheet 231 and supporting legs 232 extending from the top sheet 231. The supporting legs 232 are bonded and fixed on the first surface 211 of the carrier structure 21 around the electronic component 22 via an adhesive layer, the top sheet 231 has an upper surface 231a and a lower surface 231b opposing the upper surface 231a, and the lower surface 231b of the top sheet 231 is opposite to the inactive surface 22b of the electronic component 22.

The main material of the heat dissipation structure 23 is metal copper, and a metal anti-oxidation layer 233, such as a nickel (Ni) metal layer, can be formed on the outer surface of the heat dissipation structure 23 in order to protect the heat dissipation structure 23, and there is no metal anti-oxidation layer formed on the inner surface of the heat dissipation structure 23.

In addition, the heat conductor 24 is further disposed between the inactive surface 22b of the electronic component 22 and the lower surface 231b of the top sheet 231 of the heat dissipation structure 23, so that the heat generated by the electronic component 22 can be more efficiently conducted to the heat dissipation structure 23 and then dissipated into the environment. Preferably, the heat conductor 24 is a thermal interface material (TIM) layer, and the main material of the heat conductor 24 is metal indium (In).

Further, an interface metal layer 25 can be further formed between the heat conductor 24 and the inactive surface 22b of the electronic component 22. The interface metal layer 25 is, for example, a nickel/gold (Ni/Au) layer.

As shown in FIG. 2B, a heating process is performed, so that a first intermetallic compound (IMC) layer 261 is formed between the heat dissipation structure 23 and the heat conductor 24, and a second intermetallic compound layer 262 is formed between the heat conductor 24 and the electronic component 22, thereby obtaining the electronic package 2 of the present disclosure. As shown in FIG. 2B, the electronic package 2 of an embodiment comprises: a carrier structure 21; an electronic component 22 disposed on the carrier structure 21; a heat dissipation structure 23 disposed on the electronic component 22; a heat conductor 24 sandwiched between the electronic component 22 and the heat dissipation structure 23; a first intermetallic compound layer 261 formed between the heat dissipation structure 23 and the heat conductor 24; and a second intermetallic compound layer 262 formed between the heat conductor 24 and the electronic component 22. As such, by means that the first intermetallic compound layer 261 is formed between the heat dissipation structure 23 and the heat conductor 24, and by means that the second intermetallic compound layer 262 is formed between the heat conductor 24 and the electronic component 22, stable connections can be formed between the heat dissipation structure 23, the heat conductor 24 and the electronic component 22 to improve heat dissipation effect.

The material and the thickness of the first intermetallic compound layer 261 are different from the material and the thickness of the second intermetallic compound layer 262. For instance, the first intermetallic compound layer 261 is made of copper indium (Cu₂In), the second intermetallic compound layer 262 is made of a nickel indium compound (Ni₃In₇), and the thickness of the first intermetallic compound layer 261 (e.g., 4 μm) is greater than the thickness of the second intermetallic compound layer 262 (e.g., 2 μm).

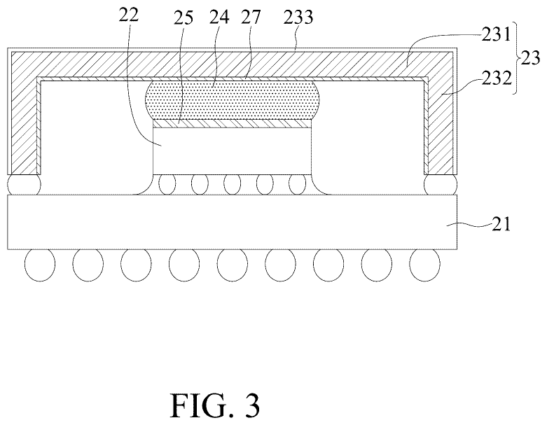

Please refer to FIG. 3, in other embodiments, a non-metal anti-oxidation layer 27, made of such as an imidazole compound, can be formed on the inner surface of the heat dissipation structure 23 (the side close to the heat conductor 24) to protect the heat dissipation structure 23. During a subsequent heating process, the non-metal anti-oxidation layer 27 will be volatilized to form the electronic package 2 with the first intermetallic compound layer 261 being formed between the heat dissipation structure 23 and the heat conductor 24 and the second intermetallic compound layer 262 being formed between the heat conductor 24 and the electronic component 22, as shown in FIG. 2B.

To sum up, in the electronic package 2 of the present disclosure, the first intermetallic compound layer 261 is formed between the heat dissipation structure 23 and the heat conductor 24, and the second intermetallic compound layer 262 is formed between the heat conductor 24 and the electronic component 22, so that stable connections can be formed between the heat dissipation structure 23, the heat conductor 24 and the electronic component 22 to improve heat dissipation effect. At the same time, the present disclosure can choose to only form a metal anti-oxidation layer (nickel layer) on the outer surface of the heat dissipation structure 23 to save process cost.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure;
an electronic component disposed on the carrier structure;
a heat conductor disposed on the electronic component;
a heat dissipation structure disposed on the electronic component, wherein the heat conductor is sandwiched between the electronic component and the heat dissipation structure;
a first intermetallic compound layer formed between the heat dissipation structure and the heat conductor; and
a second intermetallic compound layer formed between the heat conductor and the electronic component.

2. The electronic package of claim 1, wherein the first intermetallic compound layer has a material and a thickness different from a material and a thickness of the second intermetallic compound layer.

3. The electronic package of claim 1, wherein the first intermetallic compound layer is made of Cu₂In.

4. The electronic package of claim 1, wherein the second intermetallic compound layer is made of Ni₃In₇.

5. The electronic package of claim 1, wherein the first intermetallic compound layer has a thickness greater than a thickness of the second intermetallic compound layer.

6. The electronic package of claim 1, wherein the heat conductor is a thermal interface material layer.

7. The electronic package of claim 6, wherein the thermal interface material layer is made of metal indium (In).

8. The electronic package of claim 1, further comprising a metal anti-oxidation layer formed on an outer surface of the heat dissipation structure.

9. The electronic package of claim 8, wherein the metal anti-oxidation layer is made of metal nickel (Ni).

10. The electronic package of claim 1, wherein the heat dissipation structure is made of metal copper (Cu).

11. The electronic package of claim 1, wherein before the first intermetallic compound layer is formed, a non-metal anti-oxidation layer is formed on an inner surface of the heat dissipation structure.

12. The electronic package of claim 11, wherein the non-metal anti-oxidation layer is made of an imidazole compound.

13. The electronic package of claim 1, wherein before the second intermetallic compound layer is formed, an interface metal layer is formed between the heat conductor and the electronic component.

14. The electronic package of claim 13, wherein the interface metal layer is a nickel/gold (Ni/Au) layer.
